(19) United States
(12) Patent Application Publication
(10) Pub. No.: US 2010/0068630 A1
(43) Pub. Date: Mar. 18, 2010

(54) METHOD FOR MANUFACTURING PHOTO MASK

(76) Inventors: Chia-Wei Lin, Taipei City (TW); Teng-Yen Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/256,483

(22) Filed: Oct. 23, 2008

(30) Foreign Application Priority Data
Sep. 15, 2008 (TW) 097135331

(51) Int. Cl. G03F 1/00

(52) U.S. Cl. 430/5

(57) ABSTRACT

The present invention provides a method for manufacturing a photo mask. First, a transparent substrate is provided, and a patterned filling layer and a patterned mask layer are formed on the transparent substrate. Then, a crystal material layer is formed on the transparent substrate and the patterned mask layer to fill the spaces between the patterned filling layer. Thereafter, the patterned mask layer and the crystal material layer on the patterned mask layer are removed to form a patterned photonic crystal layer on the transparent substrate. Finally, the patterned filling layer is removed.

### BACKGROUND OF THE INVENTION

1. Field of the Invention

The present invention relates to a method for manufacturing a photo mask, and more particularly, to a method for manufacturing a photo mask which can improves the resolution of the exposure system.

2. Description of the Prior Art

In a manufacturing process of integrated circuits, the exposure process, which is utilized for accurately transferring patterns of photo masks to different device layers on a wafer, is certainly a key technology. With the development of the semiconductor manufacturing technology, the operating speed of the integrated circuits is improved, and the size of the integrated circuits is reduced. The size of the integrated circuits formed on the wafer is limited by the critical dimension of the pattern transferred on the wafer in the exposure process, which is also known as the resolution of the exposure system. According to Rayleigh's Criterion, the resolution of the exposure system is in direct proportion to the wavelength of the exposure light, and the resolution of the exposure system is in inverse proportion to the numerical aperture of a lens system in the exposure system. Therefore, in order to have smaller critical dimension, the wavelength of the exposure light should be shortened.

Although the exposure light can be selected to manufacture smaller electronic devices, the equipment cost and manufacturing difficulty in the manufacturing process also will be increased while the wavelength of the exposure light is being reduced. Recently, several conventional methods including off-axis illumination (OAI) method, phase shift mask (PSM) method, optical proximity correction (OPC) method and immersion technology have been proposed to improve the resolution of the exposure system.

The OAI method utilizes oblique incident exposure light which has an inclined angle with respect to the incident surface of the photo mask such that the zeroth order of the diffracted exposure light irradiating on the wafer is not perpendicular to the surface of the wafer. The depth of focus (DOF) can therefore be increased, and the resolution can be improved while the numerical aperture remains unchanged.

The PSM method utilizes a transparent phase shifter which is able to reverse the phase of an exposure light for 180 degrees and is selectively disposed on the transparent regions of a photo mask. When the exposure light passes through two adjacent patterns, and one of the patterns has a phase shift, the phases of two adjacent exposure lights passing through the two adjacent patterns have a phase difference of 180 degrees. Therefore, the contrast of the intensities between the two adjacent lights is increased, and the resolution is improved.

The OPC method takes account of the diffraction effect. That is, in order to compensate the distortion of the pattern after exposure, the pattern on the mask is adjusted to match the actually required pattern and size by combining the influence of the diffracted exposure light.

The immersion technology is depended on the principle λ′=λ/n, which indicates that the wavelength of light would be changed when passing through different mediums, where λ′ is the wavelength of the exposure light passing through a fluidic medium; λ is the wavelength of the exposure light in the air; and n is a refractive index of the fluidic medium. According to the immersion technique, the air between the optical lens and the photoresist is replaced by the fluidic medium, and therefore the wavelength of the exposure light is reduced after passing through the fluidic medium. Consequently, the resolution is improved.

However, the above-mentioned methods for improving the resolution according to prior art all require optical lenses to condense the exposure light on a wafer, so that the exposure light still suffers from the dispersion effect. This means the resolution of the exposure system must be regulated by the Rayleigh's criterion. Therefore, to overcome the dispersion effect and to improve the resolution of the exposure system are important objective to be achieved.

### SUMMARY OF THE INVENTION

It is therefore a primary objective to provide a method for manufacturing a photo mask with photonic crystal so as to raise the resolution of the exposure system.

According to a preferred embodiment of the present invention, a method for manufacturing a photo mask includes: providing a transparent substrate; covering a surface of the transparent substrate with a filling layer; patterning the filling layer to form a patterned filling layer to expose a part of the transparent substrate; forming a crystal material layer on the transparent substrate and the patterned filling layer to fill spaces between the patterned filling layer with the crystal material layer; removing the crystal material layer on the patterned filling layer to form a first patterned photonic crystal layer on the transparent substrate; and removing the patterned filling layer.

The present invention utilizes the photonic crystal manufactured on the mask to prevent the resolution of the exposure system from limitation due to dispersion effect of the exposure light, which is generated by the projection lenses. Therefore, the present invention not only can save the cost of the projection lenses, but also improve the resolution of the exposure system.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 8 are schematic diagrams illustrating a method for manufacturing a photo mask according to a preferred embodiment of the present invention.

FIG. 9 is a schematic diagram illustrating the mask of the present invention applied to the exposure process.

### DETAILED DESCRIPTION

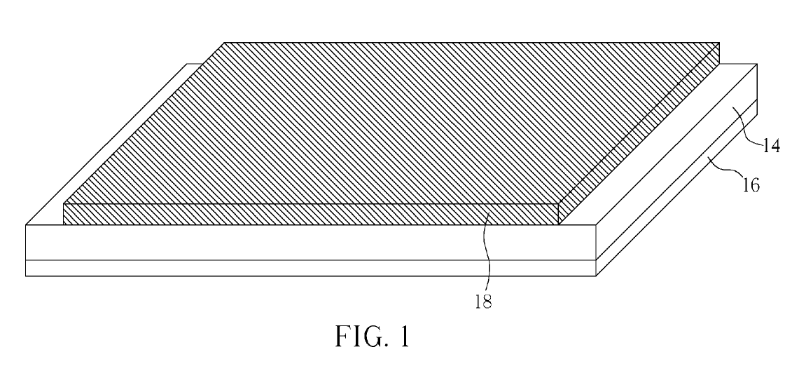

FIG. 1 through FIG. 8 are schematic diagrams illustrating a method for manufacturing a photo mask according to a preferred embodiment of the present invention. First, as shown in FIG. 1, a transparent substrate 14 is provided, wherein the transparent substrate 14 comprises a patterned projection layer 16 disposed on a surface of the transparent substrate 14. Thereafter, the other surface of the transparent substrate 14 opposite to the patterned projection layer 16 is covered with a filling layer 18.The material of the filling layer 18 comprises organic material or inorganic material.

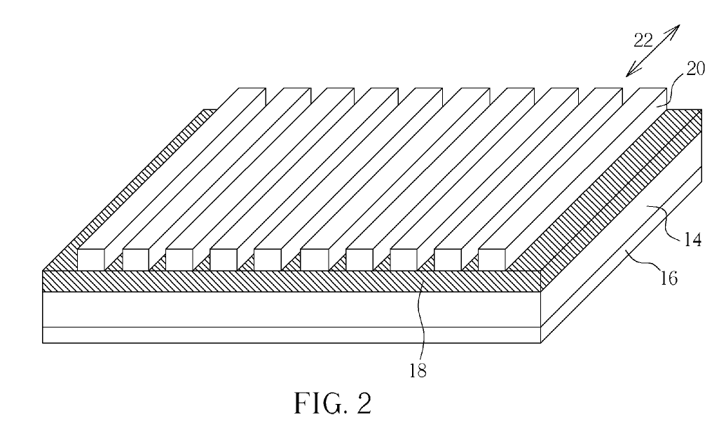

Then, as shown in FIG. 2, a patterned mask layer 20 is formed on the filling layer 18, wherein the patterned mask layer 20 can be formed by an E-beam lithographic process so as to make the filling layer 18 be exposed by the patterned mask layer 20, and the patterned mask layer 20 has the same pattern as a first photonic crystal pattern. In this embodiment, the first photonic crystal pattern is constituted by a plurality of rectangles, which are arranged along a first direction 22, but the present invention is not limited to this shape. The first photonic crystal pattern can be adjusted according to shapes of required photonic crystals.

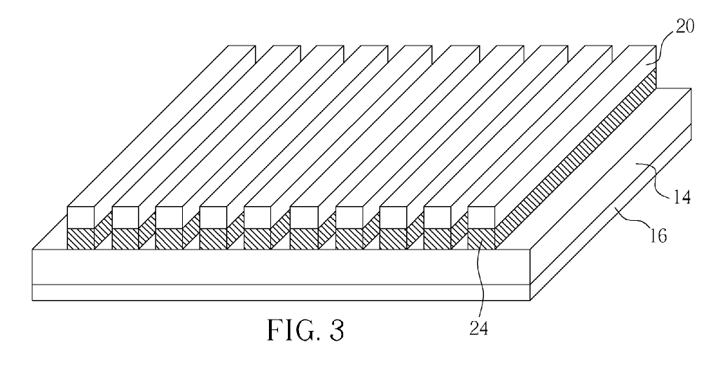

Next, as shown in FIG. 2 and FIG. 3, the patterned mask layer 20 is referred to as a mask, and the filling layer 18 is patterned to form a first patterned filling layer 24, so that the first patterned filling layer 24 has the same pattern as the patterned mask layer 20. In addition, after the filling layer 18 is patterned to form the first patterned filling layer 24, a part of the transparent substrate 14 is exposed, and the exposed transparent substrate 14 also has the same pattern as the first photonic crystal pattern. Furthermore, an etching process, preferably a dry etching process, is utilized to pattern the filling layer 18. The dry etching process can prevent the filling layer 18 under the patterned mask layer 20 from being etched so as to avoid the filling layer 18 and patterned mask layer 20 from having different patterns. Besides, in order to use the patterned mask layer 20 as a mask during patterning the filling layer 18, the filling layer 18 should have high etching selectivity compared to the patterned mask layer 20. Therefore, if the material of the filling layer 18 is an organic photoresist material, such as materials of NR7 type made by Futurrex Company©, the material of the patterned mask layer 20 is an inorganic photoresist material, such as silver sulfide or germanium sulfide. The inorganic photoresist material has high etching selectivity compared to the organic photoresist material. The present invention is not limited to the above embodiment, and the material of the filling layer 18 and the material of the patterned mask layer 20 also can be exchanged with each other.

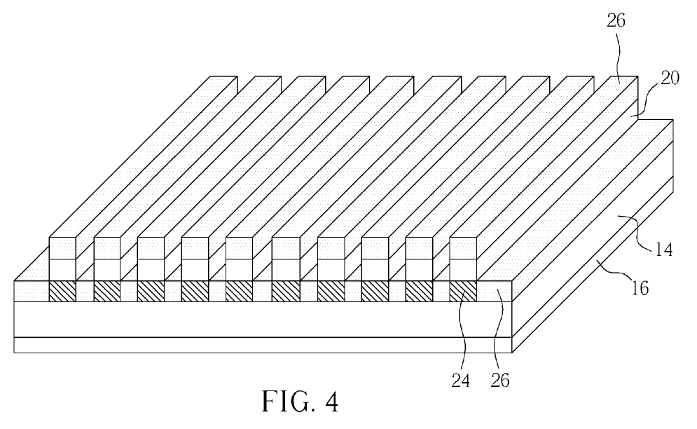

Thereafter, as shown in FIG. 4, a crystal material layer 26 is formed on the transparent substrate 14 and on the patterned mask layer 20. The crystal material layer 26 fills the spaces between the patterned filling layer 24, and covers the patterned mask layer 20. The thickness of the crystal material layer 26 is the same as the thickness of the first patterned filling layer 24. It should be noted that the material of the crystal material layer 26 comprises metal material, and the step of forming the crystal material layer 26 may be by deposition, such as a physical vapor deposition process or a chemical vapor deposition process, but not limited to this.

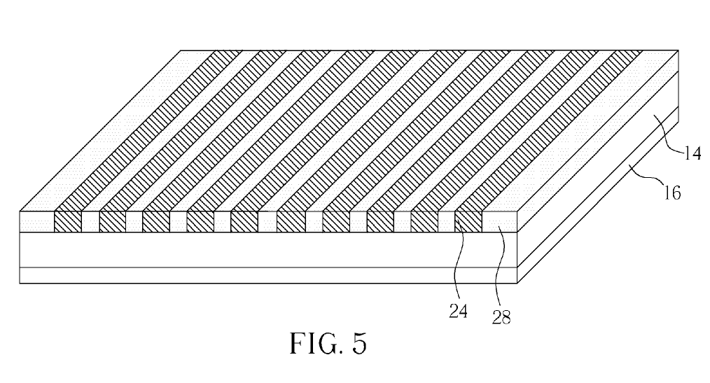

Next, as shown in FIG. 4 and FIG. 5, a lift-off process is performed to remove the crystal material layer 26 as well as the patterned mask layer 20 underlying and covered by the crystal material layer 26 so as to form a first patterned photonic crystal layer 28 on the transparent substrate 14 and between the first patterned filling layer 24. It should be noted that the thickness of the patterned mask layer 20 and the thickness of the first patterned filling layer 24 can be adjusted on condition that the thickness of the crystal material layer 26 is the same as the thickness of the first patterned filling layer 24 in order to prevent the lift-off process from being unable to be performed due to sidewalls of the patterned mask layer 20 being fully covered with the crystal material layer 26 after deposition. For example, the thickness of the patterned mask layer 20 is larger than the first patterned filling layer 24, and the thickness of the crystal material layer 26 is the same as the first patterned filling layer 24 and smaller than the thickness of the patterned mask layer 20, so that the crystal material layer 26 will not fully cover the sidewalls of the patterned mask layer 20.

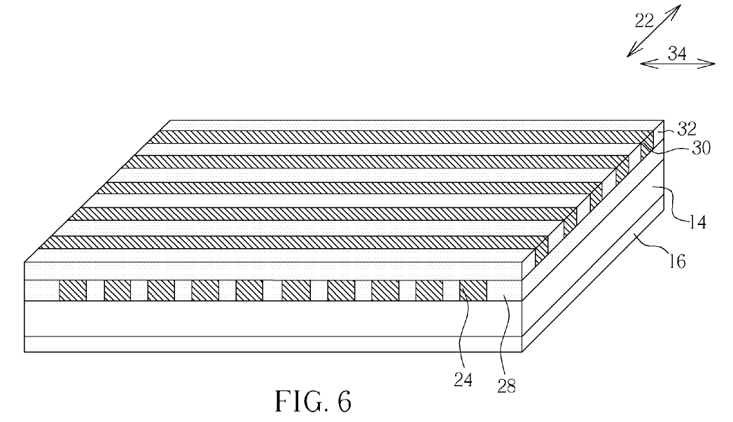

Then, as shown in FIG. 6, the step of forming the first patterned photonic crystal layer 28 is repeated to form a second patterned filling layer 30 on the first patterned photonic crystal layer 28 and a second patterned photonic crystal layer 32 disposed between the second patterned filling layer 30. The material of the second patterned photonic crystal layer 32 is the same as the material of the first patterned photonic crystal layer 28, and the material of the first patterned filling layer 24 is also the same as the material of the second patterned filling layer 30. In addition, the second patterned photonic crystal layer 32 has a second photonic crystal pattern, and the second photonic crystal pattern is constituted by a plurality of rectangles, which are arranged along a second direction 34. In this embodiment, the first direction 22 is substantially perpendicular to the second direction 34, but the present invention is not limited to this.

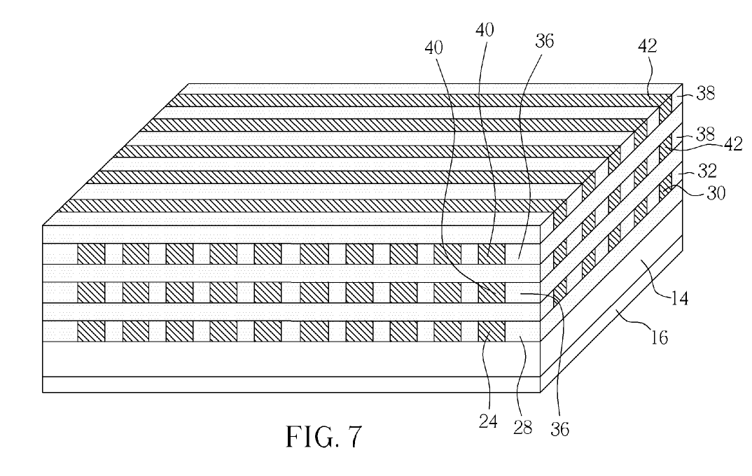

Next, as shown in FIG. 7, the step of forming the first patterned photonic crystal layer 28 is repeated to form a plurality of third patterned photonic crystal layers 36 and a plurality of fourth patterned photonic crystal layers 38 on the second patterned photonic crystal layer 32. The third patterned photonic crystal layers 36 and the first patterned photonic crystal layer 28 all have the same first photonic crystal pattern, and the fourth patterned photonic crystal layers 38 and the second patterned photonic crystal layer 32 all have the same second photonic crystal pattern. Each third patterned photonic crystal layer 36 and each fourth patterned photonic crystal layer 38 are alternately stacked in sequence on the second patterned photonic crystal layer 32 so as to have a periodic photonic crystal with the first photonic crystal pattern and the second photonic crystal pattern alternately stacked in turn on the transparent substrate 14. The spaces in the third patterned photonic crystal layers 36 are respectively filled with a third patterned filling layer 40, and the spaces in fourth patterned photonic crystal layers 38 are respectively filled with a fourth patterned filling layer 42. The first patterned filling layer 24, the second patterned filling layer 30, the third patterned filling layer 40 and the patterned filling layer 42 are stacked in sequence.

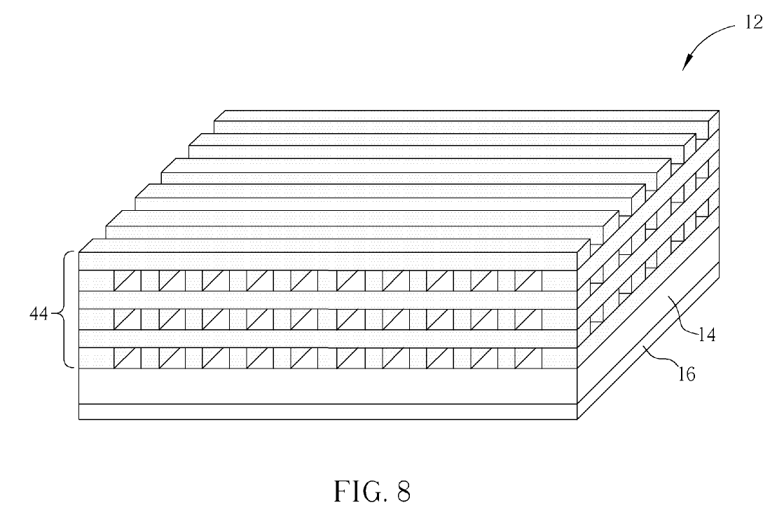

Finally, as shown in FIG. 8, the first patterned filling layer 24, the second patterned filling layer 30, the third patterned filling layers 40 and the fourth patterned filling layers 42 are removed so as to form a photonic crystal 44 on the transparent substrate 14. The mask 12 of the present invention is therefore accomplished. It is appreciated that the first patterned filling layer 24, the second patterned filling layer 30, the third patterned filling layers 40 and the fourth patterned filling layers 42 are connected to each other, so that the step of removing the first patterned filling layer 24, the second patterned filling layer 30, the third patterned filling layers 40 and the fourth patterned filling layers 42 can be implemented using a chemical solvent to dissolve all patterned filling layers. But, the chemical solvent should not damage all patterned photonic crystal layers.

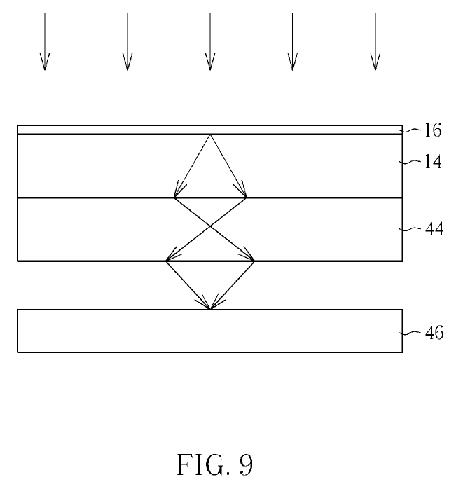

As shown in FIG. 8, according to the above-mentioned method for manufacturing the mask, a mask 12 with a photonic crystal 44 can be made. In addition, in order to describe the function of the mask manufactured by the present invention in detail, please refer to FIG. 9 together. FIG. 9 is a schematic diagram illustrating the mask of the present invention applied to the exposure process. As shown in FIG. 9, when the exposure light enters the mask, and passes through a patterned projection layer 16, the exposure light has the diffraction effect and the interference effect. Then, when the exposure light enters the transparent substrate 14, the exposure light is positively diffracted, and is scattered outward. Next, because the photonic crystal 44 has a negatively refractive index, this means the refractive index n<0, the exposure light is negatively diffracted during entering the photonic crystal 44, as shown by the arrow in FIG. 9. For this reason, the exposure light will be condensed on a surface of a wafer 46. The condensed exposure light comprises near-field light and far-field light, and the near-field light has an information of a space structure. Therefore, even if the aperture of the patterned projection layer 16 is smaller than the wavelength of the exposure light, the exposure light also can be condensed on the surface of the wafer 46. A method for manufacturing the photonic crystal 44 on the mask of the present invention not only can prevent the distortion generated by the aberration of projection lenses, but also can raise the resolution of the exposure system so as to transfer the patterned projection layer 16 smaller than the wavelength of the exposure light to the wafer 46. In addition, the mask of the present invention disposed in the exposure system does not require extra projection lenses to condense the exposure light with the pattern of the mask to the wafer 46 so as to prevent the resolution of the exposure system from being limited, which results from the dispersion effect of the exposure light generated by the projection lenses.

In summary, manufacturing a photonic crystal on the mask according to the present invention not only can save the cost of the projection lenses, but also raise the resolution of the exposure system.

Those skilled in the art will readily observe that numerous modifications and alterations of the device and method may be made while retaining the teachings of the invention.

What is claimed is:

1. A method for manufacturing a photo mask, comprising:
providing a transparent substrate, and covering a surface of the transparent substrate with a filling layer;
patterning the filling layer to form a patterned filling layer and expose a part of the transparent substrate;
forming a first patterned photonic crystal layer on the transparent substrate; and
removing the patterned filling layer.

2. The method for manufacturing the photo mask of claim 1, wherein the material of the crystal material layer comprises a metal material.

3. The method for manufacturing the photo mask of claim 1, further comprising a step of forming a second patterned photonic crystal layer on the first patterned photonic crystal layer before the step of removing the patterned filling layer.

4. The method for manufacturing the photo mask of claim 3, wherein the material of the second patterned photonic crystal layer is the same as the material of the first patterned photonic crystal layer.

5. The method for manufacturing the photo mask of claim 1, wherein the transparent substrate comprises a patterned projection layer disposed on the other surface of the transparent substrate opposite to the filling layer.
